(19) United States
(12) Patent Application Publication
(10) Pub. No.: US 2023/0384367 A1
(43) Pub. Date: Nov. 30, 2023

(54) BUMP STRUCTURE FOR MICRO-BUMPED WAFER PROBE

(71) Applicant: QUALCOMM Incorporated, San Diego, CA (US)

(72) Inventors: Yangyang SUN, San Diego, CA (US); Amer Christophe Gaetan CASSIER, La Jolla, CA (US); Stanley Seungchul SONG, San Diego, CA (US); Lily ZHAO, San Diego, CA (US); Dongming HE, San Diego, CA (US)

(21) Appl. No.: 17/804,658

(22) Filed: May 31, 2022

(51) Int. Cl. G01R 31/28; H01L 23/00

(52) U.S. Cl. CPC G01R 31/2884; H01L 24/05; H01L 24/06; H01L 24/11; H01L 24/13; H01L 24/14; H01L 2924/1431; H01L 2224/1403; H01L 2224/14051; H01L 2224/14515; H01L 2224/0603; H01L 2224/06051; H01L 2224/06515; H01L 2224/14131; H01L 2224/14132; H01L 2224/06131; H01L 2224/06132; H01L 2224/11916; H01L 2224/11903; H01L 2224/0401; H01L 2224/05573; H01L 2224/05005; H01L 2224/05017; H01L 2224/05073; H01L 2224/05541; H01L 2224/05557; H01L 2224/05147; H01L 2224/05124; H01L 2224/05647; H01L 2224/05624; H01L 2224/13147; H01L 2224/13005; H01L 2224/13016

(57) ABSTRACT

Disclosed are integrated circuit structures with interconnects of small size, also referred to micro-bumps. As pitches of micro-bumps become smaller, their sizes also become small. This makes it difficult to probe the integrated circuit structure to verify their operations. To enable probing, test pads of larger pitches are provided. The test pads, usually formed of metal, may be protected with solder caps.

### FIELD OF DISCLOSURE

This disclosure relates generally to novel bump structure for micro-bumped wafer probes.

### BACKGROUND

As interconnect pitches reduce, probes—e.g., for testing—become challenging at fine pitches. Currently, probe card for bump/solder probe is limited to 80 μm pitch. One trend in integrated circuits (IC) is 3DIC to reduce the area required to fabricate the circuit, which also has the effect of reducing area available for interconnects with corresponding reduction in pitch between interconnects. Previously, interconnects were also referred to as bumps. However, as the pitch reduction continues, the sizes of the bumps also reduce such that they are referred to as micro-bumps or pbumps.

The fabricated 3DICs are also tested to ensure proper operation. However, reductions in pitches makes it difficult to includes probes for testing of circuits. Accordingly, there is a need for systems, apparatus, and methods that enable probing of fabricated circuits when the bump pitch is significantly reduced.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary integrated circuit (IC) structure is disclosed. The IC structure may comprise a wafer comprising one or more circuits within the wafer. The IC structure may also comprise a connection layer on a top surface of the wafer. The connection layer may be conductive and configured to couple with the one or more circuits. The connection layer may comprise a plurality of micro-bump pads and a plurality of test pads. The IC structure may further comprise a plurality of test bumps on the plurality of test pads. The plurality of test bumps may be formed of solder and configured to enable test probes access to the one or more circuits. The IC structure may yet comprise a plurality of micro-bumps on the plurality of micro-bump pads. The plurality of micro-bumps may be configured to enable signal connections between the one or more circuits and one or more devices external to the IC structure. A micro-bump pitch may be less than a test bump pitch. The micro-bump pitch may be a center-to-center distance between adjacent micro-bumps, and the test bump pitch may be a center-to-center distance between adjacent test bumps.

An exemplary method of fabricating an integrated circuit (IC) structure is disclosed. The method may comprise providing a wafer comprising one or more circuits within the wafer. The method may also comprise forming a connection layer on a top surface of the wafer. The connection layer may be conductive and configured to couple with the one or more circuits. The connection layer may comprise a plurality of micro-bump pads and a plurality of test pads. The method may further comprise forming a plurality of test bumps on the plurality of test pads. The plurality of test bumps may be formed of solder and configured to enable test probes access to the one or more circuits. The method may yet comprise forming a plurality of micro-bumps on the plurality of micro-bump pads. The plurality of micro-bumps may be configured to enable signal connections between the one or more circuits and one or more devices external to the IC structure. A micro-bump pitch may be less than a test bump pitch. The micro-bump pitch may be a center-to-center distance between adjacent micro-bumps, and the test bump pitch may be a center-to-center distance between adjacent test bumps.

Another integrated circuit (IC) structure is disclosed. The IC structure may comprise a wafer comprising one or more circuits within the wafer. The IC structure may also comprise a connection layer on a top surface of the wafer. The connection layer may be conductive and configured to couple with the one or more circuits. The connection layer may comprise a plurality of first micro-bump pads, a plurality of second micro-bump pads, and a plurality of test pads. The IC structure may further comprise a plurality of test metallizations on the plurality of test pads. The plurality of test metallizations may be under bump metallizations (UBM) configured to enable test probes access to the one or more circuits. The IC structure may yet comprise a plurality of first micro-bumps and a plurality of second micro-bumps respectively on the plurality of first micro-bump pads and on the plurality of second micro-bump pads. The plurality of first micro-bumps and the plurality of second micro-bumps may be configured to enable signal connections between the one or more circuits and one or more devices external to the IC structure. A first micro-bump pitch may be less than a second micro-bump pitch and less a test metallization pitch. The first micro-bump pitch may be a center-to-center distance between adjacent first micro-bumps, the second micro-bump pitch may be a center-to-center distance between adjacent second micro-bumps, and the test metallization pitch may be a center-to-center distance between adjacent test metallizations.

Another method of fabricating integrated circuit (IC) structure is disclosed. The method may comprise providing a wafer comprising one or more circuits within the wafer. The method may also comprise forming a connection layer on a top surface of the wafer. The connection layer may be conductive and configured to couple with the one or more circuits. The connection layer may comprise a plurality of first micro-bump pads, a plurality of second micro-bump pads, and a plurality of test pads. The method may further comprise forming a plurality of test metallizations on the plurality of test pads. The plurality of test metallizations may be under bump metallizations (UBM) configured to enable test probes access to the one or more circuits. The method may yet comprise forming a plurality of first micro-bumps and a plurality of second micro-bumps respectively on the plurality of first micro-bump pads and on the plurality of second micro-bump pads. The plurality of first micro-bumps and the plurality of second micro-bumps may be configured to enable signal connections between the one or more circuits and one or more devices external to the IC structure. A first micro-bump pitch may be less than a second micro-bump pitch and less a test metallization pitch. The first micro-bump pitch may be a center-to-center distance between adjacent first micro-bumps, the second micro-bump pitch may be a center-to-center distance between adjacent second micro-bumps, and the test metallization pitch may be a center-to-center distance between adjacent test metallizations.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure.

FIG. 1 illustrates an example of a conventional IC structure connected to an external device.

FIGS. 2A and 2B respectively illustrate top and side views of another conventional IC structure adapted to enable probing the IC structure.

FIGS. 3A and 3B respectively illustrate top and side views of an IC structure configured to enable probing the IC structure in accordance with one or more aspects of the disclosure.

FIGS. 4A-4I illustrate examples of stages of fabricating an IC structure in accordance with one or more aspects of the disclosure.

FIGS. 5 and 6 illustrate differences between a conventional IC structure and an IC structure fabricated in accordance with one or more aspects of the disclosure.

FIGS. 7A-7H illustrate examples of stages of fabricating another IC structure in accordance with one or more aspects of the disclosure.

FIGS. 8 and 9 illustrate flow charts of an example method of manufacturing an IC structure in accordance with at one or more aspects of the disclosure.

FIGS. 10 and 11 illustrate flow charts of another example method of manufacturing an IC structure in accordance with at one or more aspects of the disclosure.

FIG. 12 illustrates various electronic devices which may utilize one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Traditionally, interconnects—also called bumps—of a wafer were probed with signals for testing to verify that the circuits within the wafer are in working order. A probing equipment may be capable of probing bumps whose pitches are equal to or greater than some minimum threshold pitch. If the pitches, which may be measured as a distance between adjacent bumps, are less than the minimum threshold pitch, it may not be possible to probe such bumps. The bumps whose pitches are equal to or greater than the minimum pitch, they may also be referred to as “loose pitch” bumps. Currently, loose pitch bumps may have pitches about 55-80 μm or greater.

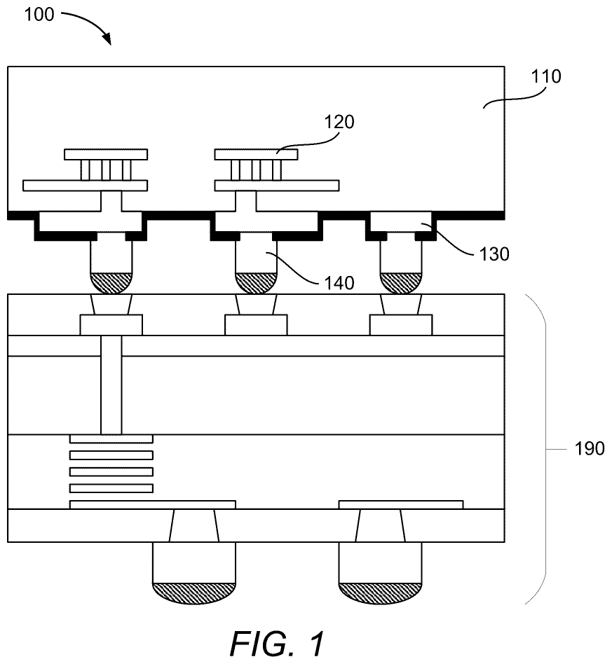

However, newer ICs typically have very small bumps with very small pitches to allow for greater integration in small form factors. FIG. 1 illustrates a conventional IC structure 100 with small bumps and small bump pitches. The IC structure 100 is illustrated as being connected to an external device 190. The conventional IC structure 100 includes a wafer 110, and circuits 120 are within the wafer 110. A conductive connection layer 130 is on a surface of the wafer 110 and is electrically coupled with the circuits 120. Interconnects 140—also referred to as micro-bumps 140—are coupled to the circuits 120 through the connection layer 130. The micro-bumps 140 enable signal connections between the circuits 120 with devices external to the IC structure 100 such as the external device 190.

The interconnects 140 are called micro-bumps 140 to emphasize that they can be rather small, and have corresponding small pitches. Table 1 below lists some interconnects, pitches, and other parameters.

TABLE 1

| | | | | | | |
|---|---|---|---|---|---|---|
| Interconnect | ~45-55 | μm | ~25 | μm | ~5-10 | μm |
| pitch | | | | | | |
| Interconnect | ~30 | μm | 10-12 | μm | 3-5 | μm |
| size | | | | | | |

| | | | |
|---|---|---|---|
| Interconnect | Micro-bump | Micro-bump | Hybrid bonding |
| type | | | |
| Probe | Skip probe | Skip probe | Probe on |
| method | Probe on | Probe on | sacrificial pad |
| | bump | sacrificial pad | |
| Probe | Memory: 10e2 | Memory: 10e2 | 3DIC: 10e4~5 |
| location | Interposer: 10e2~4 | Interposer: 10e2~4 | |
| quantity | 3DIC: 10e3~4 | 3DIC: 10e3~5 | |
| Application | HBM | HBM | Logic 3DIC |
| | Logic 3DIC | Logic 3DIC | |
| | Interposer | Interposer | |
| | Bridge die | Bridge die | |

For example, Table 1 indicates that for interconnect pitches around ˜45-55 μm, micro-bumps may be used as the interconnects of the IC structure. For these, the probing may be skipped altogether (e.g., for bridge dies). Note that the number of probes can be relatively small for memories (on the order of hundreds) and can be relatively high for 3DICs (on the order of thousands to tens of thousands). These may be applicable to high bandwidth memories (HBMs), logic 3DICs, interposers, bridge dies, etc.

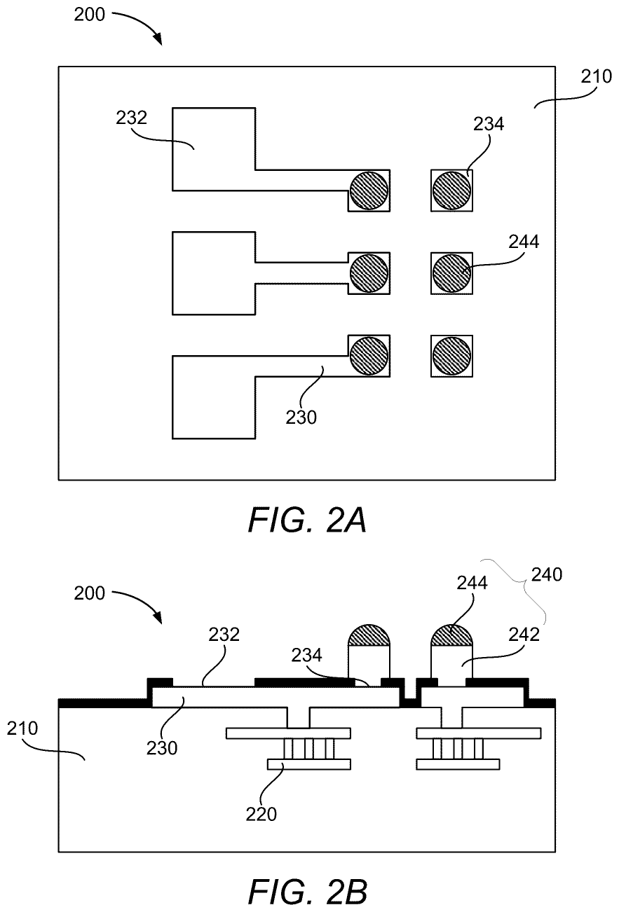

At very small pitches (e.g., ˜25 μm or less), probing may be performed on sacrificial pads instead of probing the bumps. FIGS. 2A and 2B respectively illustrate top and side views of another conventional IC structure 200 adapted to enable probing the IC structure through sacrificial pads. The IC structure 200 includes a wafer 210 with circuits 220 within the wafer 210. A conductive connection layer 330 is on a surface of the wafer 210 and is electrically coupled with the circuits 220. Micro-bumps 240 are coupled to the circuits 220 through micro-bump pads 234 of the connection layer 230. The connection layer 230 also has test pads 232 (sacrificial pads). The micro-bumps 240 enable signal connections between the circuits 220 with devices external to the IC structure 200. Each micro-bump 240 comprises copper (Cu) via 242 on a corresponding micro-bump pad 234, and a solder bump 244 on the Cu via 242.

Note that the test pads 232 of the connection layer 230 are larger and has greater pitch than the micro-bumps 240. It can be assumed that the pitch of the test pads 232 are sufficiently long to allow probing to be conducted.

While the test pads 232 do allow for probing of the IC structure 200, there are some drawbacks. The connection layer 230 is typically formed from metals such as copper or aluminum (Al). Thus, oxidation can occur at exposed surfaces of the connection layer such as at the test pads 232. Then the tip of the probe is pointy—i.e., needle-like, to scratch and penetrate the surface oxidation so that a good electrical contact can be assured. This probe-on-pad contact can damage the connection layer 230.

To address these and other issues related to conventional transistors IC structures, it is proposed to provide IC structures that allow for probe-on-solder contact even for IC structures with narrow pitch micro-bumps. In one or more embodiments, test pads with sufficient pitch are provided. However, the test pads may be protected, e.g., with solder or some other materials.

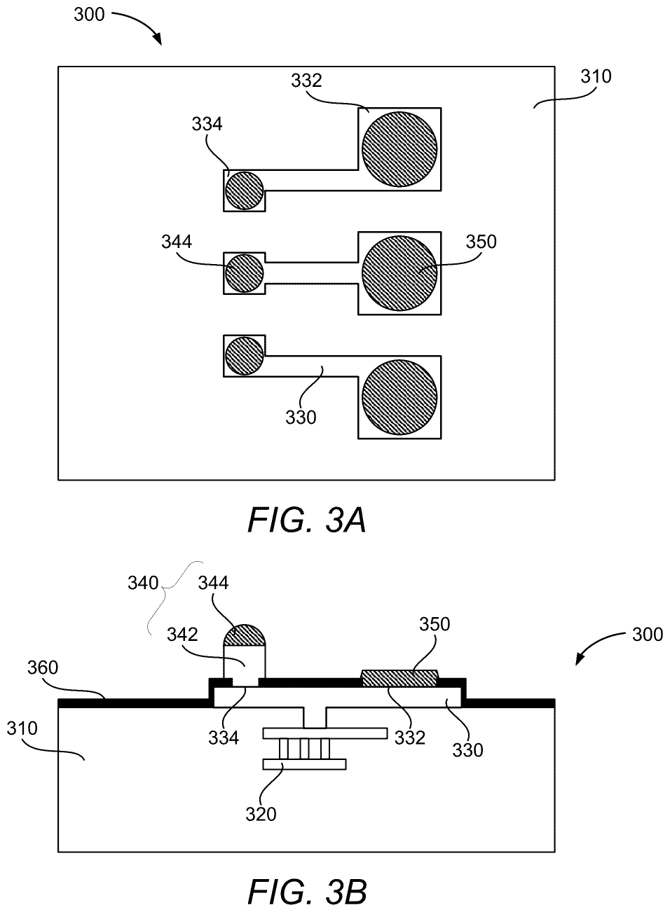

FIGS. 3A and 3B respectively illustrate top and side views of an IC structure 300 configured to enable probing the IC structure in accordance with one or more aspects of the disclosure. As seen, the IC structure 300 may comprise a wafer 310 with circuits 320 within the wafer 210. In an aspect, the circuits 320 may be circuits of a logic die such as 3DIC die.

The IC structure 300 may also comprise a connection layer 330 on a top surface of the wafer 310. It should be noted that terms “top”, “bottom”, “left”, “right”, etc. are merely used for convenience, and are not intended to specify absolute directions, unless explicitly indicated otherwise. The connection layer 330 may be conductive and configured to couple with the one or more circuits 320. The connection layer 330 may comprise a plurality of micro-bump pads 334 and a plurality of test pads 332. In an aspect, the connection layer 330 may be a metal layer, formed from metals including copper, aluminum, or any combination thereof.

The IC structure 300 may further comprise a plurality of test bumps 350 formed on the plurality of test pads 332 of the connection layer 330. The plurality of test bumps 350 may be formed of solder. The plurality of test bumps 350 may be configured to enable test probes access to the one or more circuits 320, e.g., through the connection layer 330.

The IC structure 300 may yet comprise a plurality of micro-bumps 340 formed on the plurality of micro-bump pads 334 of the connection layer 330. The plurality of micro-bumps 340 may be configured to enable signal connections between the one or more circuits 320 and one or more devices external to the IC structure 300. Each micro-bump 340 may comprise a conductive via 342 on the micro-bump pad 334 corresponding to the micro-bump 340. The conductive via 342 may be a metal via formed from metals such as copper, aluminum, or any combination thereof. Each micro-bump 340 may also comprise a solder bump 344 on the conductive via 342.

The IC structure 300 may yet further comprise a passivation layer 360 on the connection layer 330. The passivation layer 360 may cover all of the top surface of the connection layer 330 other than the plurality of micro-bump pads 334 (which may be covered by the plurality of micro-bumps 340) and the plurality of test pads 332 (which may be covered by the plurality of test bumps 350). In this way, exposure of the connection layer 330 is limited to thereby limit oxidation buildup.

In an aspect, heights of the micro-bumps 340 may be greater than heights of the test bumps 350. Alternatively or in addition thereto, lateral areas of the test bumps 350 may be larger than lateral areas of the micro-bumps 340. In a further aspect, the plurality of test bumps 350 may not behave like the micro-bumps. That is, the test bumps 350 may not be configured to enable signal connections between the one or more circuits 320 and one or more devices external to the IC structure 300.

Note that the test bumps 350 may be larger and may have greater pitch than the micro-bumps 340. For ease of reference, pitches of the test bumps 350 (center-to-center distance between adjacent test bumps 350) may be referred to as test bump pitches, and the pitches of the micro-bumps 340 (center-to-center distance between adjacent micro-bumps 340) may be referred to as micro-bump pitches. Then, it may be said that the micro-bump pitch is less than the test bump pitch. In an aspect, the test bump pitch may be sufficiently long to allow probing to be conducted. That is, the test bump pitch may be a “loose-pitch”. Alternatively or in addition thereto, in another aspect, the micro-bump pitch may be a “fine-pitch”, which may describe a pitch that is too small (e.g., less than the minimum probe pitch threshold) for probing to occur.

Note that probing may take place on the test bumps 350. Since the test bumps 350 are formed from solder, this allows probe-on-solder contact. Since solder is malleable, probe with flat tip may be used, which reduces damage to the test bumps 350. Also, any damage to the test bumps 350 may be fixed or at least mitigated through solder reflow, which can reshape the test bumps 350. Further, the test pads 332 may be from contamination since they can be protected by the test bumps 350.

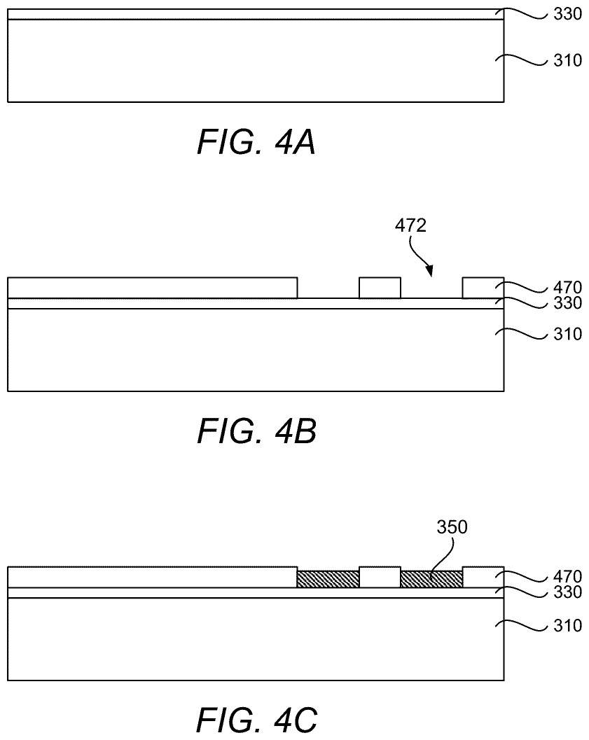

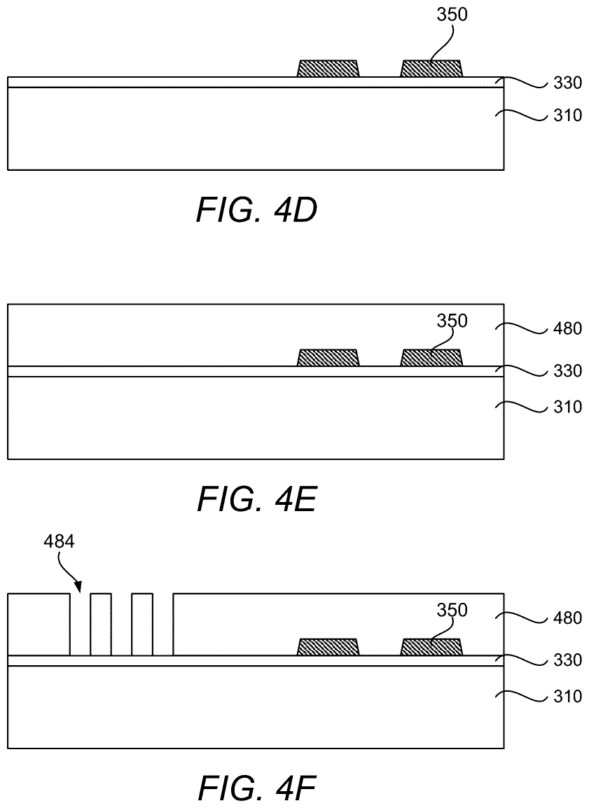

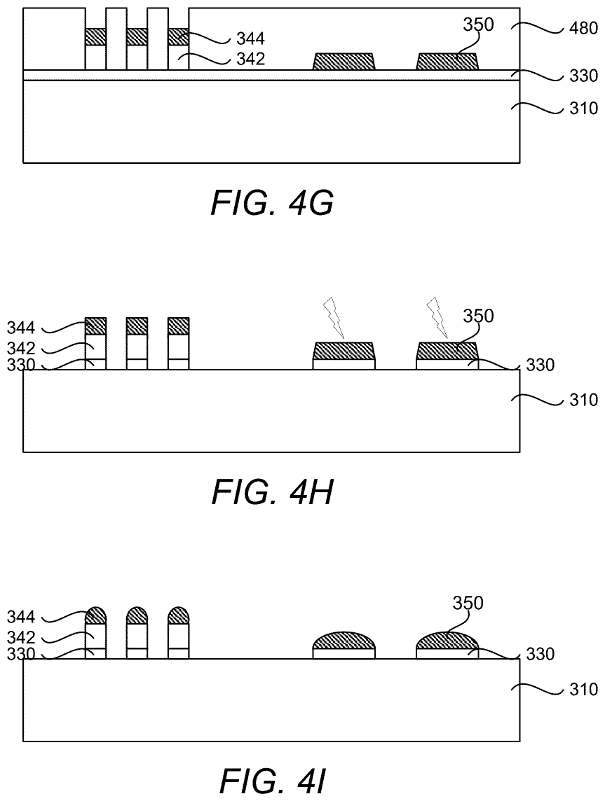

FIGS. 4A-4I illustrate examples of stages of fabricating an IC structure in accordance with one or more aspects of the disclosure. In this instance, the stages may apply to the fabrication of the IC structure 300.

FIG. 4A illustrates a stage in which the connection layer 330 is deposited on the wafer 310. The circuits 320 are not illustrated so as to reduce clutter.

FIG. 4B illustrates a stage in which a first photoresist layer 470 is deposited on the connection layer 330. The deposited first photoresist layer 470 may be patterned to form test pad openings 472 that expose the plurality of test pads 332 (not shown in FIG. 4B).

FIG. 4C illustrates a stage in which solder material is deposited in the test pad openings 472. As a result, the plurality of test bumps 350 may be formed. The heights of the test bumps 350 may be determined, at least in part, by the height of the first photoresist layer 470.

FIG. 4D illustrates a stage in which the first photoresist layer 470 may be removed.

FIG. 4E illustrates a stage in which a second photoresist layer 480 is deposited on the connection layer 330 and on the test bumps 350. In an aspect, the second photoresist layer 480 may be thicker than the first photoresist layer 470 deposited in the stage of FIG. 4B.

FIG. 4F illustrates a stage in which deposited second photoresist layer 480 is patterned to form micro-bump pad openings 484 that expose the plurality of micro-bump pads 334 (not shown in FIG. 4F).

FIG. 4G illustrates a stage in which conductive material is deposited in the micro-bump pad openings 484 to form the conductive vias 342 on the plurality of micro-bump pads 334. Also, solder material may be deposited in the micro-bump pad openings 484 to form the solder bumps 344 on the conductive vias 342.

FIG. 4H illustrates a stage in which the second photoresist layer 480 may be removed. Thereafter, probing may be conducted on the test bumps 350 to test the IC structure.

FIG. 4I illustrates a stage in which solder reflow may be performed. In an aspect, the stage of FIG. 4I may be performed if the testing conducted in stage of FIG. 4H indicates that the IC structure operates properly.

The fabrication stages illustrated in FIGS. 4A-4I may be referred to as “two-step plating” since the test bumps 350 and the solder bumps 344 (of the micro-bump 340) may be plated in different steps. While not shown, the passivation layer 360 may be formed, e.g., after the stage of FIG. 4H or after the stage of FIG. 4I.

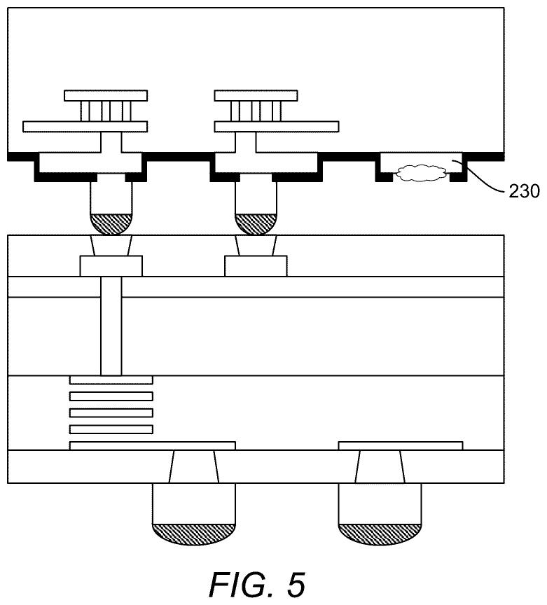

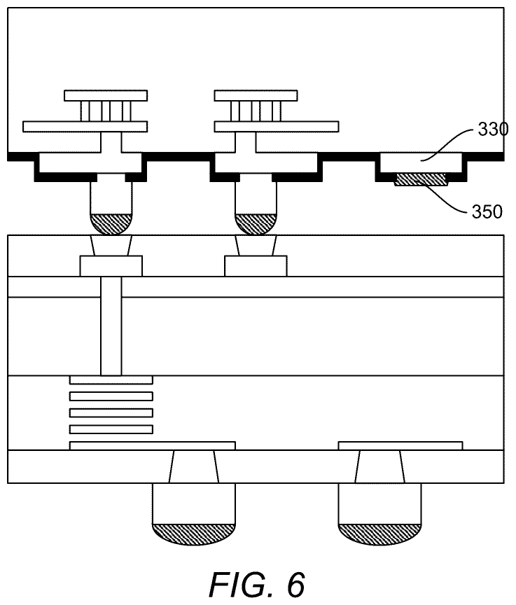

Recall from above that unlike the conventional IC structure (such as the IC structure 200), the proposed IC structure (such as the IC structure 300) protects the test pad from damage. FIG. 5 illustrates that the connection layer 230 of the conventional IC structure may suffer damage from the probe tips. However, FIG. 6 illustrates that the connection layer 330 of the proposed IC structure is protected from damage from the probe tips by the test bump 350.

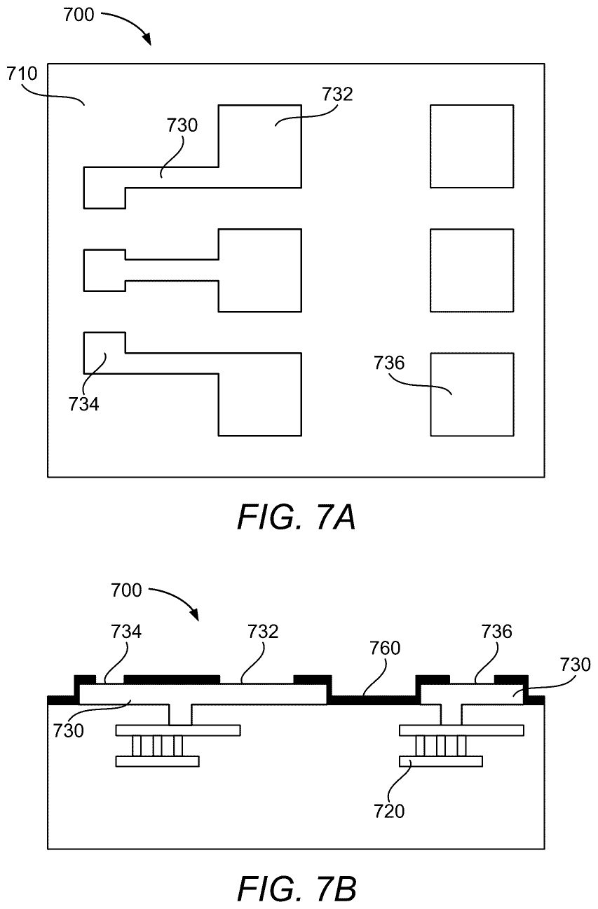

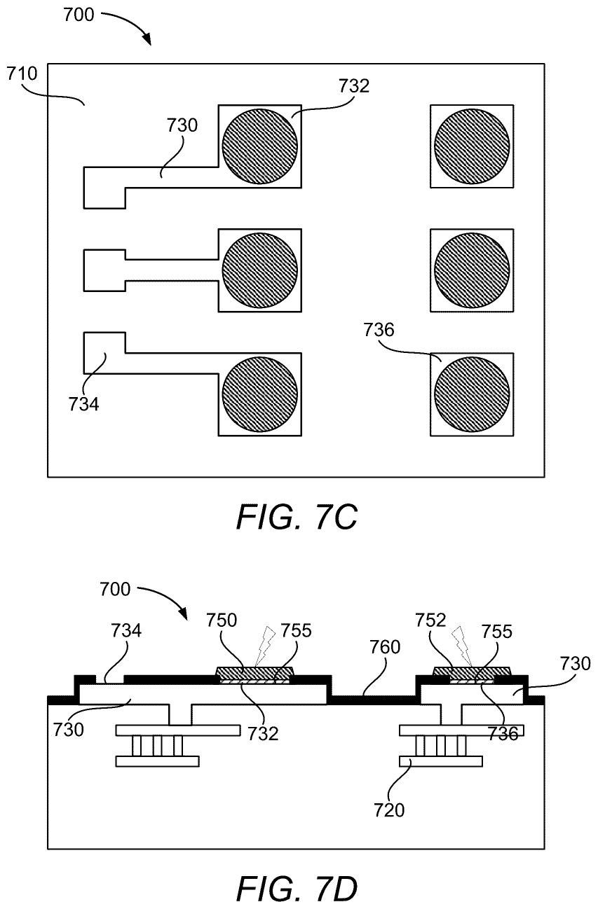

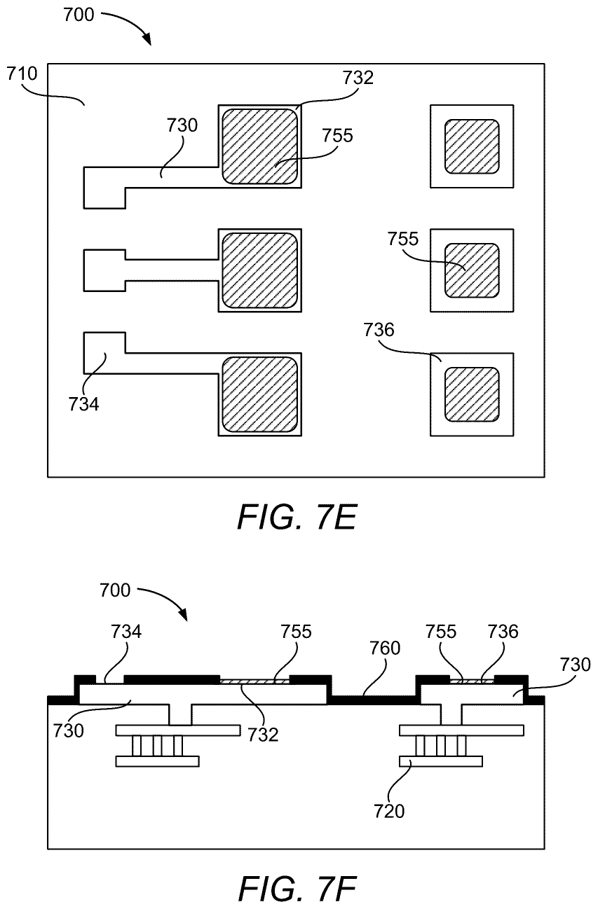

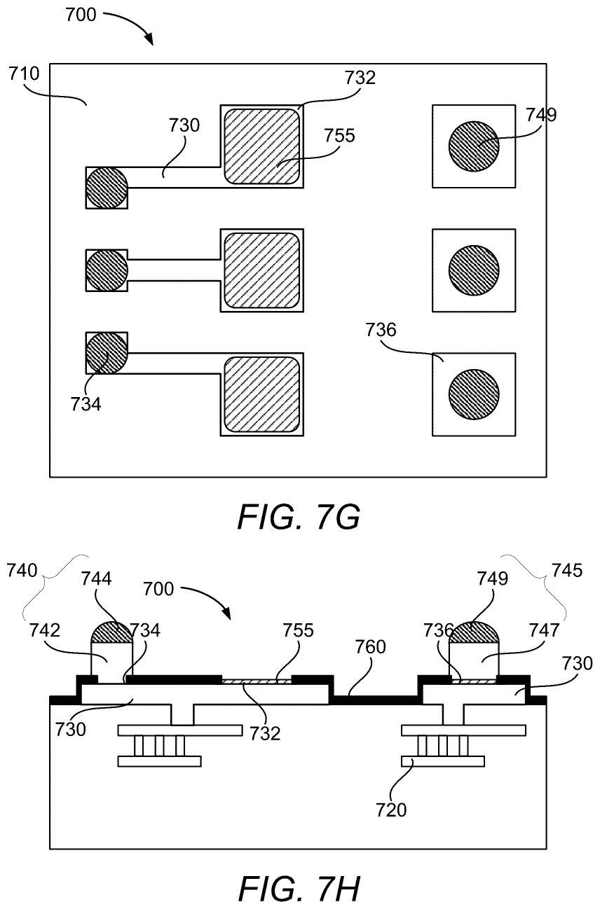

FIGS. 7A-7H illustrate examples of stages of fabricating another IC structure in accordance with one or more aspects of the disclosure. Before describing the stages, the fabricated IC structure 700, illustrated in FIGS. 7G and 7H, will be described initially. FIGS. 7G and 7H respectively illustrate top and side views. As will be made clear, the IC structure 700 can allow probing through the test pads and also through micro-bumps that are used for chip attachment (e.g., with other dies).

As seen in FIGS. 7G and 7H, the IC structure 700 may comprise a wafer 710 with circuits 720 within the wafer 210. In an aspect, the circuits 720 may be circuits of a logic die such as 3DIC die.

The IC structure 700 may also comprise a connection layer 730 on a top surface of the wafer 710. The connection layer 730 may be conductive and configured to couple with the one or more circuits 720. The connection layer 730 may comprise a plurality of first micro-bump pads 734, a plurality of second micro-bump pads 736, and a plurality of test pads 732. In an aspect, the connection layer 730 may be a metal layer, formed from metals including copper, aluminum, or any combination thereof.

The IC structure 700 may further comprise a plurality of test metallizations 755 on the plurality of test pads 732. The plurality of test metallizations 755 may be under bump metallizations (UBM), and may enable test probes access to the one or more circuits 720, e.g., through the connection layer 730. Alternatively or in addition thereto, the test metallizations 755 may also be formed on the plurality of second micro-bump pads 736.

The IC structure 700 may yet comprise a plurality of first micro-bumps 740 formed on the plurality of first micro-bump pads 734 of the connection layer 730. The plurality of first micro-bumps 740 may be configured to enable signal connections between the one or more circuits 720 and one or more devices external to the IC structure 700. Each first micro-bump 740 may comprise a first conductive via 742 on the first micro-bump pad 734 corresponding to the first micro-bump 740. The first conductive via 742 may be a metal via formed from metals such as copper, aluminum, or any combination thereof. Each first micro-bump 740 may also comprise a first solder bump 744 on the first conductive via 742.

The IC structure 700 may also comprise a plurality of second micro-bumps 745 formed on the plurality of second micro-bump pads 736 of the connection layer 730. The plurality of second micro-bumps 745 may be configured to enable signal connections between the one or more circuits 720 and one or more devices external to the IC structure 700. Each second micro-bump 745 may comprise a second conductive via 747 on the second micro-bump pad 736 corresponding to the second micro-bump 745. The second conductive via 747 may be a metal via formed from metals such as copper, aluminum, or any combination thereof. Each second micro-bump 745 may also comprise a second solder bump 749 on the second conductive via 747.

The IC structure 700 may yet further comprise a passivation layer 760 on the connection layer 730. The passivation layer 760 may cover all of the top surface of the connection layer 730 other than the plurality of first micro-bump pads 734 (which may be covered by the plurality of first micro-bumps 740), plurality of second micro-bump pads 736 (which may be covered by the plurality of second micro-bumps 745), and the plurality of test pads 732 (which may be covered by the plurality of test metallizations 755). In this way, exposure of the connection 730 is limited to thereby limit oxidation buildup. Note that in in FIG. 7G illustrating the top view, the passivation layer 760 is not shown, so that details of other components such as the connection layer 730 can be shown.

In an aspect, heights of the first micro-bumps 740 and/or heights of the second micro-bumps 745 may be greater than heights of the test metallizations 755. Alternatively or in addition thereto, lateral areas of the test metallizations 755 may be larger than lateral areas of the first micro-bumps 740. Note that the lateral areas of the test metallizations 755 and the lateral areas of the second micro-bumps 745 may be substantially equal. In this context, substantially equal is intended to indicate that areas are within the margins of the equipment used in fabricating the IC structure 700. For example, if it is known that the equipment's deviation from indicated settings by ±1%, then the areas should be within 2% of each other to be substantially equal.

In a further aspect, the plurality of test metallizations 755 may not behave like the micro-bumps. That is, the test metallizations 755 may not be configured to enable signal connections between the one or more circuits 720 and one or more devices external to the IC structure 700.

Note that both test metallizations 755 and the second micro-bumps 745 may be larger and have greater pitch than the first micro-bumps 740. For ease of reference, pitches of the test metallizations 755 (center-to-center distance between adjacent test metallizations 755) may be referred to as test metallizations pitches, the pitches of the first micro-bumps 740 (center-to-center distance between adjacent first micro-bumps 740) may be referred to as first micro-bump pitches, and the pitches of the second micro-bumps 745 (center-to-center distance between adjacent second micro-bumps 745) may be referred to as second micro-bump pitches. Then, it may be said that the first micro-bump pitch is less than the test metallization pitch and also less than the second micro-bump pitch. In an aspect, both the test metallization pitch and the second micro-bump pitch may be sufficiently long to allow probing to be conducted. That is, the both the test metallization pitch and the second micro-bump pitches may be loose-pitches. In an aspect, the test metallization pitch and the second micro-bump pitch may be substantially equal. Again, substantially equal is intended to indicate that the pitches are within the fabrication equipment's margin. Alternatively or in addition thereto, in another aspect, the first micro-bump pitch may be a fine-pitch.

Now, the different stages will be described. FIGS. 7A and 7B showing top and side views respectively, illustrate a stage in which the connection layer 730 comprising the plurality of test pads 732, the plurality of first micro-bump pads 734, and the plurality of second micro-bump pads 736 are formed. Again, the passivation layer 760 is not shown in FIG. 7A showing the top view for reasons described above. This will be common to FIGS. 7C and 7E also showing top views of other stages.

FIGS. 7C and 7D showing top and side views respectively, illustrate a stage in which the test metallizations 755 are formed on the plurality of test pads 732. Optionally, in an aspect, test metallizations 755—e.g., UBMs—may also be formed on the plurality second micro-bump pads 736. Then temporary test solder caps 750 may be formed on the test metallizations 755, and temporary micro-bump solder caps 752 may be formed on the plurality second micro-bump pads 736 (or on the UBMs).

After forming the temporary test solder caps 750 and the temporary micro-bump solder caps 752, probing may be conducted through the temporary test solder caps 750 and/or through the temporary micro-bump solder caps 752. This is because both have loose-pitches. This means that test pads 732 may be need only in areas where there are micro-bumps that have fine pitches (such as the first micro-bumps 740). Test pads 732 need not be provided in areas where there are micro-bumps with loose pitches (such as the second micro-bumps 745).

FIGS. 7E and 7F showing top and side views respectively, illustrate a stage in which the temporary test solder caps 750 and the temporary micro-bump solder caps 752 may be removed.

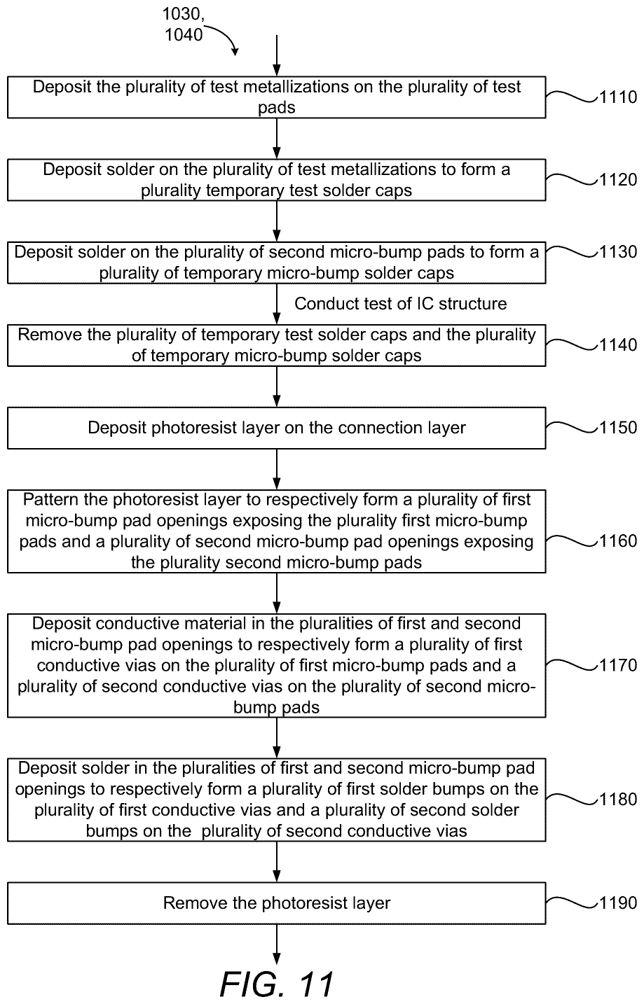

Finally, FIGS. 7G and 7H illustrates a stage in which the first micro-bumps 740 may be formed on the first micro-bump pads 734, and the second micro-bumps 745 may be formed on the second micro-bump pads 736. In an aspect, the fabrication stages illustrated in FIGS. 4F-4I may be modified to form the first and second micro-bumps 740, 745 (e.g. see flow chart of FIG. 11).

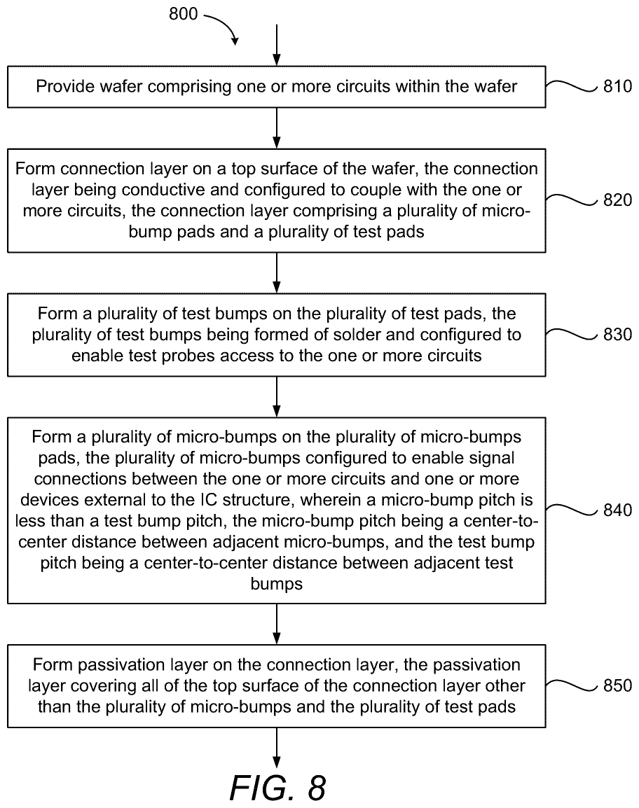

FIG. 8 illustrates a flow chart of an example method 800 of manufacturing an IC structure (e.g., IC structure 300) in accordance with at one or more aspects of the disclosure. In block 810, a wafer 310 comprising one or more circuits 320 may be provided.

In block 820, a connection layer 330 may be formed on a top surface of the wafer 310. The connection layer 330 may be conductive. The connection layer 330 may also be configured to couple with the one or more circuits 320. The connection layer 330 may comprise a plurality of micro-bump pads 334 and a plurality of test pads 332.

In block 830, a plurality of test bumps 350 may be formed on the plurality of test pads 332. The plurality of test bumps 350 may be formed of solder and configured to enable test probes access to the one or more circuits 320.

In block 840, a plurality of micro-bumps 340 may be formed on the plurality of micro-bump pads 334. The plurality of micro-bumps 340 may be configured to enable signal connections between the one or more circuits 320 and one or more devices external to the IC structure 300. The micro-bump pitch may be less than the test bump pitch.

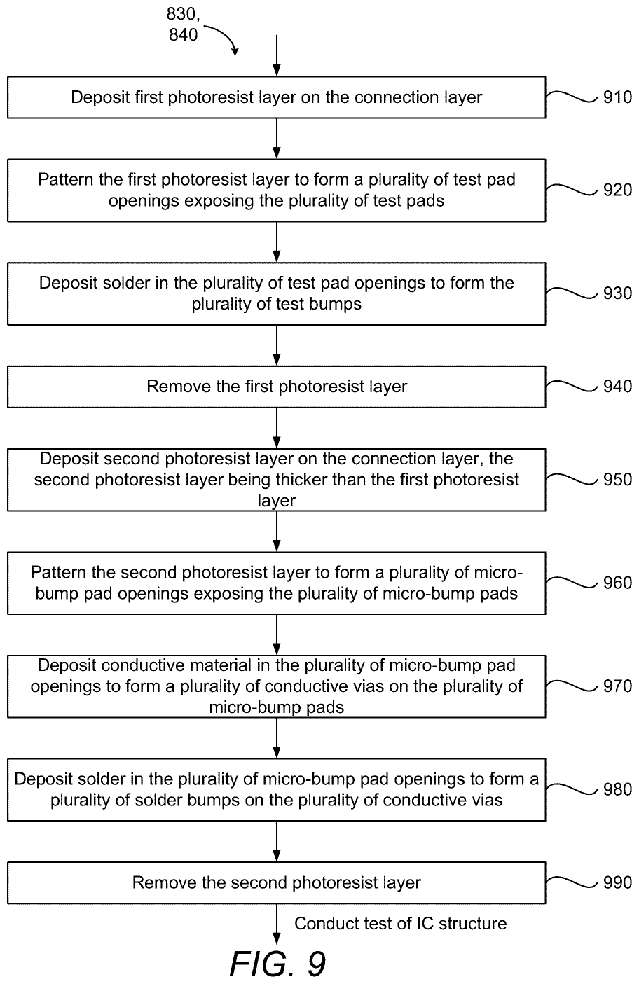

FIG. 9 illustrates a flow chart of an example process to implement blocks 830 and 840. Blocks 910-940 may correspond to block 830, and blocks 950-990 may correspond to block 840. In block 910, a first photoresist layer 470 may be deposited on the connection layer 330 (see FIG. 4B).

In block 920, the first photoresist layer 470 may be patterned to form a plurality of test pad openings 472 exposing the plurality test pads 332 (see FIG. 4B).

In block 930, solder may be deposited in the plurality of test pad openings 472 to form the plurality of test bumps 350 (see FIG. 4C).

In block 940, the first photoresist layer 470 may be removed (see FIG. 4D).

In block 950, a second photoresist layer 480 may be deposited on the connection layer 330. Note that the second photoresist layer 480 may be thicker than the first photoresist layer 470 (see FIG. 4E).

In block 960, the second photoresist layer 480 may be patterned to form a plurality of micro-bump pad openings 484 exposing the plurality micro-bump pads 334 (see FIG. 4F).

In block 970, conductive material may be deposited in the plurality of micro-bump pad openings 484 to form a plurality of conductive vias 342 on the plurality of micro-bump pads 334 (see FIG. 4G).

In block 980, solder may be deposited in the plurality of micro-bump pad openings 484 to form the a plurality of solder bumps 344 on the plurality of conductive vias 342 (see FIG. 4G).

In block 990, the second photoresist layer 480 may be removed (see FIG. 4H). Thereafter the IC structure 300 may be probed.

Referring back to FIG. 8, in block 850, a passivation layer 360 may be formed on the connection layer 330. The passivation layer 360 may cover all of the top surface of the connection layer 330 other than the plurality of micro-bump pads 334 and the plurality of test pads 332.

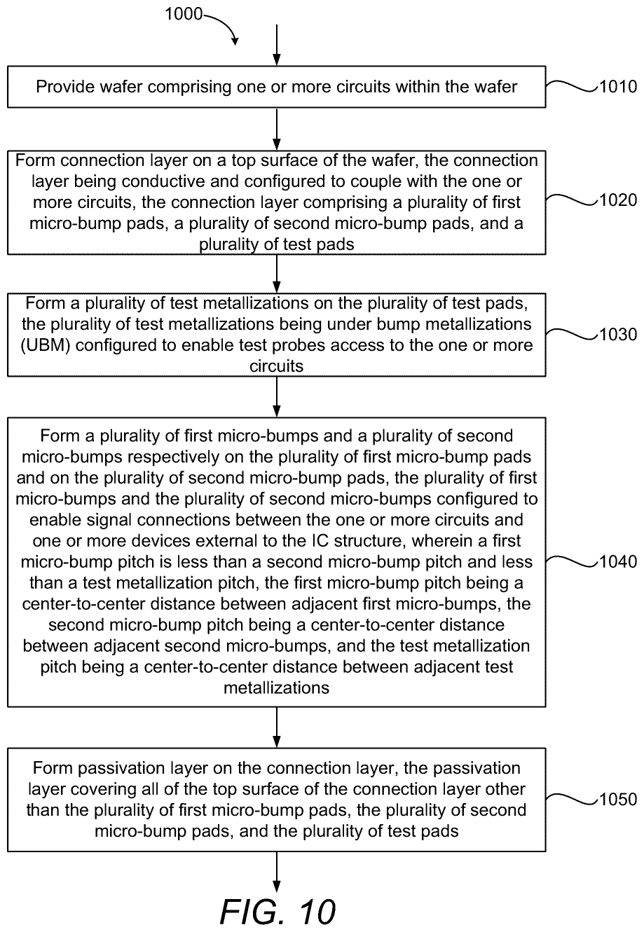

FIG. 10 illustrates a flow chart of an example method 1000 of manufacturing an IC structure (e.g., IC structure 700) in accordance with at one or more aspects of the disclosure. In block 1010, a wafer 710 comprising one or more circuits 720 may be provided.

In block 1020, a connection layer 730 may be formed on a top surface of the wafer 710. The connection layer 730 may be conductive. The connection layer 730 may also be configured to couple with the one or more circuits 720. The connection layer 730 may comprise a plurality of first micro-bump pads 734, a plurality of second micro-bump pads 736, and a plurality of test pads 732.

In block 1030, a plurality of test metallizations 755 may be formed on the plurality of test pads 732. The plurality of test metallizations 755 may be under bump metallizations (UBM) configured to enable test probes access to the one or more circuits 720.

In block 1040, a plurality of first micro-bumps 740 and a plurality of second micro-bumps 745 may be respectively formed on the plurality of first micro-bump pads 734 and on the plurality of second micro-bump pads 736. The plurality of first micro-bumps 740 and the plurality of second micro-bumps 745 may be configured to enable signal connections between the one or more circuits 720 and one or more devices external to the IC structure 700.

FIG. 11 illustrates a flow chart of a process to implement blocks 1030 and 1040. Blocks 1110-1140 may correspond to block 1030, and blocks 1150-1190 may correspond to block 1040. In block 1110, the plurality of test metallizations 755 may be deposited on the plurality test pads 732 (see FIGS. 7C and 7D).

In block 1120, solder may be deposited on the plurality of test metallizations 755 to form a plurality of temporary test solder caps 750 (see FIGS. 7C and 7D).

In block 1130, solder may be deposited on the plurality of second micro-bump pads 736 to form a plurality of temporary micro-bump solder caps 752 (see FIGS. 7C and 7D). Thereafter, the IC structure 700 may be probed through the plurality of temporary test solder caps 750 and/or the plurality of temporary micro-bump solder caps 752.

In block 1140, the plurality of temporary test solder caps 750 and the plurality of temporary micro-bump solder caps 752 may be removed (see FIGS. 7C and 7D).

In block 1150, a photoresist layer may be deposited on the connection layer 730 (modification of stage of FIG. 4E).

In block 1160, the photoresist layer may be patterned to respectively form a plurality of first micro-bump pad openings exposing the plurality first micro-bump pads 734 and a plurality of second micro-bump pad openings exposing the plurality second micro-bump pads 736 (modification of stage of FIG. 4F).

In block 1170, conductive material may be deposited in the pluralities of first and second micro-bump pad openings to respectively form a plurality of first conductive vias 742 on the plurality of first micro-bump pads 734 and a plurality of second conductive vias 747 on the plurality of second micro-bump pads 736 (modification of stage of FIG. 4G).

In block 1180, solder may be deposited in the pluralities of first and second micro-bump pad openings to respectively form a plurality of first solder bumps 744 on the plurality of first conductive vias 742 and a plurality of second solder bumps 749 on the plurality of second conductive vias 747 (modification of stage of FIG. 4G).

In block 1190, the photoresist layer may be removed (modification of stage of FIG. 4H).

Referring back to FIG. 10, in block 1050, a passivation layer 760 may be formed on the connection layer 730. The passivation layer 760 may cover all of the top surface of the connection layer 730 other than the plurality of first micro-bump pads 734, the plurality of second micro-bump pads 736, and the plurality of test pads 732.

It will be appreciated that the foregoing fabrication processes and related discussion are provided merely as a general illustration of some of the aspects of the disclosure and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations. Further, it will be appreciated that the illustrated configurations and descriptions are provided merely to aid in the explanation of the various aspects disclosed herein. For example, the number and location of the inductors, the metallization structure may have more or less conductive and insulating layers, the cavity orientation, size, whether it is formed of multiple cavities, is closed or open, and other aspects may have variations driven by specific application design features, such as the number of antennas, antenna type, frequency range, power, etc. Accordingly, the forgoing illustrative examples and associated figures should not be construed to limit the various aspects disclosed and claimed herein.

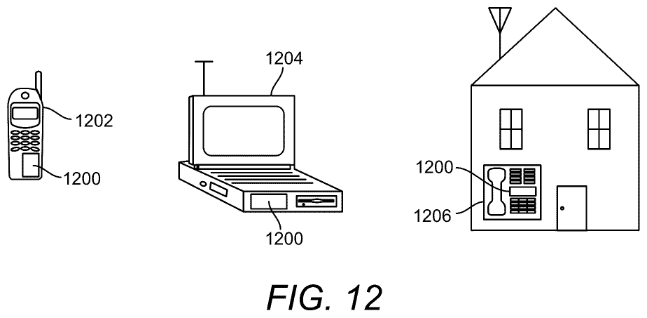

FIG. 12 illustrates various electronic devices 1200 that may be integrated with any of the aforementioned devices in accordance with various aspects of the disclosure. For example, a mobile phone device 1202, a laptop computer device 1204, and a fixed location terminal device 1206 may each be considered generally user equipment (UE) and may include one or more IC structures (e.g., 300, 700) as described herein. The devices 1202, 1204, 1206 illustrated in FIG. 12 are merely exemplary. Other electronic devices may also include the RF filter including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

Implementation examples are described in the following numbered clauses:
Clause 1: An integrated circuit (IC) structure, comprising: a wafer comprising one or more circuits within the wafer; a connection layer on a top surface of the wafer, the connection layer being conductive and configured to couple with the one or more circuits, the connection layer comprising a plurality of micro-bump pads and a plurality of test pads; a plurality of test bumps on the plurality of test pads, the plurality of test bumps being formed of solder and configured to enable test probes access to the one or more circuits; and a plurality of micro-bumps on the plurality of micro-bump pads, the plurality of micro-bumps configured to enable signal connections between the one or more circuits and one or more devices external to the IC structure, wherein a micro-bump pitch is less than a test bump pitch, the micro-bump pitch being a center-to-center distance between adjacent micro-bumps, and the test bump pitch being a center-to-center distance between adjacent test bumps.
Clause 2: The IC structure of clause 1, wherein a height of at least one micro-bump is greater than a height of at least one test bump.
Clause 3: The IC structure of any of clauses 1-2, wherein a lateral area of at least one test bump is larger than a lateral area of at least one micro-bump.
Clause 4: The IC structure of any of clauses 1-3, wherein the plurality of test bumps are not configured to enable signal connections between the one or more circuits and one or more devices external to the IC structure.
Clause 5: The IC structure of any of clauses 1-4, further comprising: a passivation layer on the connection layer, the passivation layer covering all of the top surface of the connection layer other than the plurality of micro-bump pads and the plurality of test pads.
Clause 6: The IC structure of clause 5, wherein the connection layer is a metal layer.
Clause 7: The IC structure of clause 6, wherein the connection layer is formed from copper (Cu), aluminum (Al), or both.
Clause 8: The IC structure of any of clauses 1-7, wherein each micro-bump comprises: a conductive via on a micro-bump pad corresponding to the micro-bump; and a solder bump on the conductive via.
Clause 9: IC structure of clause 8, wherein the conductive via is a metal via.
Clause 10: The IC structure of clause 9, wherein the conductive via is formed from copper (Cu).
Clause 11: The IC structure of any of clauses 1-10, wherein the one or more circuits within the wafer are circuits of a logic die.
Clause 12: The IC structure of any of clauses 1-11, wherein the IC structure is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.
Clause 13: A method of fabricating an integrated circuit (IC) structure, the method comprising: providing a wafer comprising one or more circuits within the wafer; forming a connection layer on a top surface of the wafer, the connection layer being conductive and configured to couple with the one or more circuits, the connection layer comprising a plurality of micro-bump pads and a plurality of test pads; forming a plurality of test bumps on the plurality of test pads, the plurality of test bumps being formed of solder and configured to enable test probes access to the one or more circuits, forming a plurality of micro-bumps on the plurality of micro-bump pads, the plurality of micro-bumps configured to enable signal connections between the one or more circuits and one or more devices external to the IC structure, wherein a micro-bump pitch is less than a test bump pitch, the micro-bump pitch being a center-to-center distance between adjacent micro-bumps, and the test bump pitch being a center-to-center distance between adjacent test bumps.
Clause 14: The method of clause 13, wherein a height of at least one first micro-bump is greater than a height of at least one test bump.
Clause 15: The method of any of clauses 13-14, wherein a lateral area of at least one test bump is larger than a lateral area of at least one micro-bump.
Clause 16: The method of any of clauses 13-15, wherein forming the plurality of test bumps comprises: depositing a first photoresist layer on the connection layer; patterning the first photoresist layer to form a plurality of test pad openings exposing the plurality test pads; depositing solder in the plurality of test pad openings to form the plurality of test bumps; and removing the first photoresist layer.
Clause 17: The method of clause 16, wherein forming the plurality of micro-bumps comprises: depositing a second photoresist layer on the connection layer, the second photoresist layer being thicker than the first photoresist layer; patterning the second photoresist layer to form a plurality of micro-bump pad openings exposing the plurality of micro-bump pads; depositing conductive material in the plurality of micro-bump pad openings to form a plurality of conductive vias on the plurality of micro-bump pads; depositing solder in the plurality of micro-bump pad openings to form a plurality of solder bumps on the plurality of conductive vias; and removing the second photoresist layer.
Clause 18: The method of clause 16, wherein the plurality of conductive vias are formed from copper (Cu).
Clause 19: The method of any of clauses 13-18, further comprising: forming a passivation layer on the connection layer, the passivation layer covering all of the top surface of the connection layer other than the plurality of micro-bump pads and the plurality of test pads.
Clause 20: The method of any of clauses 13-19, wherein the connection layer is formed from copper (Cu), aluminum (Al), or both.
Clause 21: The method of any of clauses 13-20, wherein the one or more circuits within the wafer are circuits of a logic die.
Clause 22: An integrated circuit (IC) structure, comprising: a wafer comprising one or more circuits within the wafer; a connection layer on a top surface of the wafer, the connection layer being conductive and configured to couple with the one or more circuits, the connection layer comprising a plurality of first micro-bump pads, a plurality of second micro-bump pads, and a plurality of test pads; a plurality of test metallizations on the plurality of test pads, the plurality of test metallizations being under bump metallizations (UBM) configured to enable test probes access to the one or more circuits; and a plurality of first micro-bumps and a plurality of second micro-bumps respectively on the plurality of first micro-bump pads and on the plurality of second micro-bump pads, the plurality of first micro-bumps and the plurality of second micro-bumps configured to enable signal connections between the one or more circuits and one or more devices external to the IC structure, wherein a first micro-bump pitch is less than a second micro-bump pitch and less a test metallization pitch, the first micro-bump pitch being a center-to-center distance between adjacent first micro-bumps, the second micro-bump pitch being a center-to-center distance between adjacent second micro-bumps, and the test metallization pitch being a center-to-center distance between adjacent test metallizations.
Clause 23: The IC structure of clause 22, wherein the second micro-bump pitch and the test metallization pitch are substantially equal.
Clause 24: The IC structure of any of clauses 22-23, wherein a height of at least one first micro-bump is greater than a height of at least one test metallization, or wherein a height of at least one second micro-bump is greater than the height of the at least one test metallization, or both.
Clause 25: The IC structure of any of clauses 22-24, wherein a lateral area of at least one test metallization is larger than a lateral area of at least one first micro-bump.
Clause 26: The IC structure of any of clauses 22-25, wherein the plurality of test metallizations are not configured to enable signal connections between the one or more circuits and one or more devices external to the IC structure.
Clause 27: The IC structure of any of clauses 22-26, further comprising: a passivation layer on the connection layer, the passivation layer covering all of the top surface of the connection layer other than the plurality of first micro-bump pads, the plurality of second micro-bump pads, and the plurality of test pads.
Clause 28: The IC structure of any of clauses 22-27, wherein the connection layer is formed from copper (Cu), aluminum (Al), or both.
Clause 29: The IC structure of any of clauses 22-28, wherein each first micro-bump comprises: a first conductive via on a first micro-bump pad corresponding to the first micro-bump; and a first solder bump on the first conductive via, and wherein each second micro-bump comprises: a second conductive via on a second micro-bump pad corresponding to the second micro-bump; and a second solder bump on the second conductive via.
Clause 30: The IC structure of clauses 29, wherein the first conductive via is formed from copper (Cu), or wherein the second conductive via is formed from Cu, or both.
Clause 31: The IC structure of any of clauses 22-30, wherein the one or more circuits within the wafer are circuits of a logic die.
Clause 32: The IC structure of any of clauses 22-31, wherein the IC structure is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.
Clause 33: A method of fabricating an integrated circuit (IC) structure, the method comprising: providing a wafer comprising one or more circuits within the wafer; forming a connection layer on a top surface of the wafer, the connection layer being conductive and configured to couple with the one or more circuits, the connection layer comprising a plurality of first micro-bump pads, a plurality of second micro-bump pads, and a plurality of test pads; forming a plurality of test metallizations on the plurality of test pads, the plurality of test metallizations being under bump metallizations (UBM) configured to enable test probes access to the one or more circuits; and forming a plurality of first micro-bumps and a plurality of second micro-bumps respectively on the plurality of first micro-bump pads and on the plurality of second micro-bump pads, the plurality of first micro-bumps and the plurality of second micro-bumps configured to enable signal connections between the one or more circuits and one or more devices external to the IC structure, wherein a first micro-bump pitch is less than a second micro-bump pitch and less a test metallization pitch, the first micro-bump pitch being a center-to-center distance between adjacent first micro-bumps, the second micro-bump pitch being a center-to-center distance between adjacent second micro-bumps, and the test metallization pitch being a center-to-center distance between adjacent test metallizations.
Clause 34: The method of clause 33, wherein the second micro-bump pitch and the test metallization pitch are substantially equal.
Clause 35: The method of any of clauses 33-34, wherein a height of at least one first micro-bump is greater than a height of at least one test metallization, or wherein a height of at least one second micro-bump is greater than the height of the at least one test metallization, or both.
Clause 36: The method of any of clauses 33-35, wherein a lateral area of at least one test metallization is larger than a lateral area of at least one first micro-bump.
Clause 37: The method of any of clauses 33-36, wherein forming the plurality of test metallizations comprises: depositing the plurality of test metallizations on the plurality test pads; depositing solder on the plurality of test metallizations to form a plurality of temporary test solder caps; depositing solder on the plurality of second micro-bump pads to form a plurality of temporary micro-bump solder caps; and removing the plurality of temporary test solder caps and the plurality of temporary micro-bump solder caps.
Clause 38: The method of clause 37, wherein forming the plurality of first micro-bumps and the plurality of second micro-bumps comprises: depositing a photoresist layer on the connection layer; patterning the photoresist layer to respectively form a plurality of first micro-bump pad openings exposing the plurality first micro-bump pads and a plurality of second micro-bump pad openings exposing the plurality second micro-bump pads; depositing conductive material in the pluralities of first and second micro-bump pad openings to respectively form a plurality of first conductive vias on the plurality of first micro-bump pads and a plurality of second conductive vias on the plurality of second micro-bump pads; depositing solder in the pluralities of first and second micro-bump pad openings to respectively form a plurality of first solder bumps on the plurality of first conductive vias and a plurality of second solder bumps on the plurality of second conductive vias; and removing the photoresist layer.
Clause 39: The method of clause 38, wherein the plurality of first conductive via are formed from copper (Cu), or wherein the plurality of second conductive via are formed from Cu, or both.
Clause 40: The method of any of clauses 33-39, further comprising: forming a passivation layer on the connection layer, the passivation layer covering all of the top surface of the connection layer other than the plurality of first micro-bump pads, the plurality of second micro-bump pads, and the plurality of test pads.
Clause 41: The method of any of clauses 33-40, wherein the connection layer is formed from copper (Cu), aluminum (Al), or both.
Clause 42: The method of any of clauses 33-41, wherein the one or more circuits within the wafer are circuits of a logic die.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5.

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage or mode of operation. Furthermore, a particular feature and/or structure can be combined with one or more other features and/or structures. Moreover, at least a portion of the apparatus described herein can be configured to perform at least a portion of a method described herein.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Those skilled in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that—although a dependent claim can refer in the claims to a specific combination with one or one or more claims—other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. An integrated circuit (IC) structure, comprising:
a wafer comprising one or more circuits within the wafer;
a connection layer on a top surface of the wafer, the connection layer being conductive and configured to couple with the one or more circuits, the connection layer comprising a plurality of micro-bump pads and a plurality of test pads;
a plurality of test bumps on the plurality of test pads, the plurality of test bumps being formed of solder and configured to enable test probes access to the one or more circuits; and
a plurality of micro-bumps on the plurality of micro-bump pads, the plurality of micro-bumps configured to enable signal connections between the one or more circuits and one or more devices external to the IC structure,
wherein a micro-bump pitch is less than a test bump pitch, the micro-bump pitch being a center-to-center distance between adjacent micro-bumps, and the test bump pitch being a center-to-center distance between adjacent test bumps.

2. The IC structure of claim 1, wherein a height of at least one micro-bump is greater than a height of at least one test bump.

3. The IC structure of claim 1, wherein a lateral area of at least one test bump is larger than a lateral area of at least one micro-bump.

4. The IC structure of claim 1, wherein the plurality of test bumps are not configured to enable signal connections between the one or more circuits and one or more devices external to the IC structure.

5. The IC structure of claim 1, further comprising:
a passivation layer on the connection layer, the passivation layer covering all of the top surface of the connection layer other than the plurality of micro-bump pads and the plurality of test pads.

6. The IC structure of claim 5, wherein the connection layer is formed from copper (Cu), aluminum (Al), or both.

7. The IC structure of claim 1, wherein each micro-bump comprises:
a conductive via on a micro-bump pad corresponding to the micro-bump; and
a solder bump on the conductive via.

8. The IC structure of claim 7, wherein the conductive via is formed from copper (Cu).

9. The IC structure of claim 1, wherein the one or more circuits within the wafer are circuits of a logic die.

10. The IC structure of claim 1, wherein the IC structure is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

11. A method of fabricating an integrated circuit (IC) structure, the method comprising:
providing a wafer comprising one or more circuits within the wafer;
forming a connection layer on a top surface of the wafer, the connection layer being conductive and configured to couple with the one or more circuits, the connection layer comprising a plurality of micro-bump pads and a plurality of test pads;
forming a plurality of test bumps on the plurality of test pads, the plurality of test bumps being formed of solder and configured to enable test probes access to the one or more circuits; and
forming a plurality of micro-bumps on the plurality of micro-bump pads, the plurality of micro-bumps configured to enable signal connections between the one or more circuits and one or more devices external to the IC structure,
wherein a micro-bump pitch is less than a test bump pitch, the micro-bump pitch being a center-to-center distance between adjacent micro-bumps, and the test bump pitch being a center-to-center distance between adjacent test bumps.

12. The method of claim 11, wherein a height of at least one first micro-bump is greater than a height of at least one test bump.

13. The method of claim 11, wherein a lateral area of at least one test bump is larger than a lateral area of at least one micro-bump.

14. The method of claim 11, wherein forming the plurality of test bumps comprises:
depositing a first photoresist layer on the connection layer;
patterning the first photoresist layer to form a plurality of test pad openings exposing the plurality test pads;
depositing solder in the plurality of test pad openings to form the plurality of test bumps; and
removing the first photoresist layer.

15. The method of claim 14, wherein forming the plurality of micro-bumps comprises:
depositing a second photoresist layer on the connection layer, the second photoresist layer being thicker than the first photoresist layer;
patterning the second photoresist layer to form a plurality of micro-bump pad openings exposing the plurality of micro-bump pads;
depositing conductive material in the plurality of micro-bump pad openings to form a plurality of conductive vias on the plurality of micro-bump pads;
depositing solder in the plurality of micro-bump pad openings to form a plurality of solder bumps on the plurality of conductive vias; and
removing the second photoresist layer.

16. The method of claim 11, further comprising:
forming a passivation layer on the connection layer, the passivation layer covering all of the top surface of the connection layer other than the plurality of micro-bump pads and the plurality of test pads.

17. The method of claim 11, wherein the one or more circuits within the wafer are circuits of a logic die.

18. An integrated circuit (IC) structure, comprising:
a wafer comprising one or more circuits within the wafer;
a connection layer on a top surface of the wafer, the connection layer being conductive and configured to couple with the one or more circuits, the connection layer comprising a plurality of first micro-bump pads, a plurality of second micro-bump pads, and a plurality of test pads;
a plurality of test metallizations on the plurality of test pads, the plurality of test metallizations being under bump metallizations (UBM) configured to enable test probes access to the one or more circuits; and
a plurality of first micro-bumps and a plurality of second micro-bumps respectively on the plurality of first micro-bump pads and on the plurality of second micro-bump pads, the plurality of first micro-bumps and the plurality of second micro-bumps configured to enable signal connections between the one or more circuits and one or more devices external to the IC structure,
wherein a first micro-bump pitch is less than a second micro-bump pitch and less a test metallization pitch, the first micro-bump pitch being a center-to-center distance between adjacent first micro-bumps, the second micro-bump pitch being a center-to-center distance between adjacent second micro-bumps, and the test metallization pitch being a center-to-center distance between adjacent test metallizations.

19. The IC structure of claim 18, wherein the second micro-bump pitch and the test metallization pitch are substantially equal.

20. The IC structure of claim 18,
wherein a height of at least one first micro-bump is greater than a height of at least one test metallization, or
wherein a height of at least one second micro-bump is greater than the height of the at least one test metallization, or
both.

21. The IC structure of claim 18, wherein a lateral area of at least one test metallization is larger than a lateral area of at least one first micro-bump.

22. The IC structure of claim 18, further comprising:
a passivation layer on the connection layer, the passivation layer covering all of the top surface of the connection layer other than the plurality of first micro-bump pads, the plurality of second micro-bump pads, and the plurality of test pads.

23. The IC structure of claim 18,
wherein each first micro-bump comprises:
a first conductive via on a first micro-bump pad corresponding to the first micro-bump; and
a first solder bump on the first conductive via, and
wherein each second micro-bump comprises:
a second conductive via on a second micro-bump pad corresponding to the second micro-bump; and
a second solder bump on the second conductive via.

24. The IC structure of claim 18, wherein the one or more circuits within the wafer are circuits of a logic die.

25. The IC structure of claim 18, wherein the IC structure is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

26. A method of fabricating an integrated circuit (IC) structure, the method comprising:
providing a wafer comprising one or more circuits within the wafer;
forming a connection layer on a top surface of the wafer, the connection layer being conductive and configured to couple with the one or more circuits, the connection layer comprising a plurality of first micro-bump pads, a plurality of second micro-bump pads, and a plurality of test pads;
forming a plurality of test metallizations on the plurality of test pads, the plurality of test metallizations being under bump metallizations (UBM) configured to enable test probes access to the one or more circuits; and
forming a plurality of first micro-bumps and a plurality of second micro-bumps respectively on the plurality of first micro-bump pads and on the plurality of second micro-bump pads, the plurality of first micro-bumps and the plurality of second micro-bumps configured to enable signal connections between the one or more circuits and one or more devices external to the IC structure,
wherein a first micro-bump pitch is less than a second micro-bump pitch and less than a test metallization pitch, the first micro-bump pitch being a center-to-center distance between adjacent first micro-bumps, the second micro-bump pitch being a center-to-center distance between adjacent second micro-bumps, and the test metallization pitch being a center-to-center distance between adjacent test metallizations.

27. The method of claim 26, wherein forming the plurality of test metallizations comprises:
depositing the plurality of test metallizations on the plurality test pads;
depositing solder on the plurality of test metallizations to form a plurality of temporary test solder caps;
depositing solder on the plurality of second micro-bump pads to form a plurality of temporary micro-bump solder caps; and
removing the plurality of temporary test solder caps and the plurality of temporary micro-bump solder caps.

28. The method of claim 27, wherein forming the plurality of first micro-bumps and the plurality of second micro-bumps comprises:
depositing a photoresist layer on the connection layer;
patterning the photoresist layer to respectively form a plurality of first micro-bump pad openings exposing the plurality first micro-bump pads and a plurality of second micro-bump pad openings exposing the plurality second micro-bump pads;
depositing conductive material in the pluralities of first and second micro-bump pad openings to respectively form a plurality of first conductive vias on the plurality of first micro-bump pads and a plurality of second conductive vias on the plurality of second micro-bump pads;
depositing solder in the pluralities of first and second micro-bump pad openings to respectively form a plurality of first solder bumps on the plurality of first conductive vias and a plurality of second solder bumps on the plurality of second conductive vias; and
removing the photoresist layer.

29. The method of claim 26, further comprising:
forming a passivation layer on the connection layer, the passivation layer covering all of the top surface of the connection layer other than the plurality of first micro-bump pads, the plurality of second micro-bump pads, and the plurality of test pads.

30. The method of claim 26, wherein the one or more circuits within the wafer are circuits of a logic die.
